(19) United States
(12) Patent Application Publication
(10) Pub. No.: US 2013/0113169 A1
(43) Pub. Date: May 9, 2013

(54) POWER INPUT DEVICE AND VACUUM PROCESSING APPARATUS USING THE SAME

(71) Applicant: Canon Anelva Corporation, Kawasaki-shi (JP)

(72) Inventor: Kyosuke Sugi, Fuchu-shi (JP)

(73) Assignee: CANON ANELVA CORPORATION, Kawasaki-shi (JP)

(21) Appl. No.: 13/728,607

(22) Filed: Dec. 27, 2012

Related U.S. Application Data
(63) Continuation of application No. PCT/JP2010/004676, filed on Jul. 21, 2010.

(51) Int. Cl. H01L 21/683

(52) U.S. Cl. CPC H01L 21/6833
USPC 279/128

(57) ABSTRACT

A power input mechanism includes a first stationary conductive member, a second stationary conductive member, a stationary insulating member which is fixed to a housing and insulates the first stationary conductive member and the second stationary conductive member from each other, a first rotary conductive member, a second rotary conductive member, a rotary insulating member which is fixed to a support column and insulates the first rotary conductive member and the second rotary conductive member from each other, a first power input member which supplies a first voltage to a substrate holder via the first rotary conductive member and the first stationary conductive member, and a second power input member which supplies a second voltage to the substrate holder via the second rotary conductive member and the second stationary conductive member.

### TECHNICAL FIELD

The present invention relates to a power input device and a vacuum processing apparatus using the same. The present invention relates, more particularly, to a power input device suitable for inputting power to an electrostatic chuck of a substrate holder rotatably accommodated in a vacuum processing chamber, and a vacuum processing apparatus using the same.

### BACKGROUND ART

A conventional power input device will be described with reference to FIGS. 6A, 6B, and 7. FIG. 6B is a detailed view of a power input mechanism shown in FIG. 6A. In a configuration disclosed in PTL1, a substrate holder 601 provided in a power input device is rotatably held inside a vacuum chamber 630, as shown in, for example, FIG. 6A. The substrate holder 601 has a surface, which slides in a surface contact state about a rotation axis C of a rotary support column 602 of the substrate holder 601, between the rotary support column 602 and a base 603 which supports a load including the rotary support column 602. Providing a rotary joint formed by a plurality of conductive annular members 604 arranged in a concentric circular shape makes it possible to stably supply power to the electrode of an electrostatic chuck without causing instability in rotation of the substrate holder 601. A bipolar electrostatic chuck which inputs power to a plurality of electrodes is configured by arranging a plurality of mechanisms shown in FIGS. 6A and 6B in the rotation axis direction to sandwich insulating members 605a and 605b between them, thereby maintaining the insulated state between the plurality of electrodes.

In this structure, to attain a stable rotation operation, the insulating members 605a and 605b must be disposed on the side of the rotary support column 602 of the substrate holder 601 and on the side of the base 603 which supports a load including the rotary support column 602, respectively, so that a minimum gap 607 is formed between the insulating members 605a and 605b. On the other hand, a rotary joint does not provide a perfect seal and leaks a fluid albeit in a very small amount, so it is a common practice to form a drain port to discharge the leaked fluid to the exterior. The fluid leaked from the rotary joint falls outside a circulation flow channel which circulates cooling water for cooling the electrostatic chuck. Hence, even if pure water having a resistance value controlled to 10 MΩ·cm or more circulates through the internal flow channel, the resistance value of pure water leaked from the rotary joint lowers in a short time. As a result, a fluid having a low resistance value is present between the plurality of electrodes, so the plurality of electrodes may be electrically connected to each other through the fluid depending on the circumstances involved. When the above-mentioned power input mechanism is applied to a bipolar electrostatic chuck, the insulated state between the bipolar electrodes cannot be maintained, so it may become impossible to perform an operation for chucking the substrate by electrostatic attraction, resulting in product defects due to failures in chucking of the substrate.

As a countermeasure against this problem, the conventional technique has attempted to use a so-called labyrinth structure 708 for the shape of the insulating members 605a and 605b arranged on the sides of the rotary support column 602 and base 603, respectively, as shown in FIG. 7. In the labyrinth structure 708, a fluid 709 leaked from the rotary joint falls into a receptacle 710, which is disposed on the insulating member on the side of the base 603, by the action of gravity. A drain port 706 is partially formed in the receptacle 710 to discharge the fluid that has fallen into the receptacle 710 to the exterior, thereby preventing the fluid 709 from being connected to the other electrode side.

### CITATION LIST

### Patent Literature

PTL1: Japanese Patent Laid-Open No. 2008-156746

### SUMMARY OF INVENTION

### Technical Problem

In addition to a substrate holder which holds a substrate horizontally to the ground surface, as shown in FIGS. 6A, 6B, and 7, a substrate processing apparatus which performs deposition or etching upon pivoting a substrate holder while a normal to the substrate holding surface of the substrate holder is set perpendicular to the direction of gravity has come to be widely used in recent years, in terms of an increase in size of substrates and space saving of a substrate processing apparatus. The labyrinth structure 708 which discharges the fluid 709 by the action of gravity, as described with reference to FIG. 6B, is inapplicable to such a substrate processing apparatus.

It is an object of the present invention to provide a power input technique which allows stable power input to a substrate holder having a plurality of electrodes, and is applicable to an apparatus which processes a substrate upon pivoting a substrate holder while a normal to the substrate holding surface of the substrate holder is set perpendicular to the direction of gravity.

### Solution to Problem

In order to achieve the above-mentioned object, according to the present invention, there is provided a power input device characterized by comprising:

a substrate holder which is accommodated in a vacuum chamber and capable of holding a substrate;

a support column connected to the substrate holder;

a housing which rotatably supports the support column;

a rotary drive unit which rotates the substrate holder via the support column;

a power input unit which inputs externally supplied power to the substrate holder via the support column; and

a coolant supply mechanism which circulates an externally supplied coolant to the substrate holder,

the power input unit including

a first stationary conductive member disposed in the housing,

a second stationary conductive member which is disposed in the housing at a position spaced apart from the first stationary conductive member, and is insulated from the first stationary conductive member,

a first rotary conductive member disposed on the support column in sliding contact with the first stationary conductive member,

a second rotary conductive member which is disposed on the support column in sliding contact with the second stationary conductive member, and insulated from the first rotary conductive member,

a first power input member which supplies a first voltage to the substrate holder via the first rotary conductive member and the first stationary conductive member, and

a second power input member which supplies a second voltage to the substrate holder via the second rotary conductive member and the second stationary conductive member,

wherein the coolant circulates through a space formed by a surface of the support column, the housing opposed to the surface of the support column, the first rotary conductive member, the first stationary conductive member, the second rotary conductive member, and the second stationary conductive member, and the space is connected to the coolant supply mechanism via a coolant flow channel formed in the support column.

### Advantageous Effects of Invention

According to the present invention, it is possible to provide a power input technique which allows stable power input to a substrate holder having a plurality of electrodes, and is applicable to an apparatus which processes a substrate upon pivoting a substrate holder while a normal to the substrate holding surface of the substrate holder is set perpendicular to the direction of gravity.

Other features and advantages of the present invention will be apparent from the following descriptions taken in conjunction with the accompanying drawings, in which like reference characters designate the same or similar parts throughout the figures thereof.

### BRIEF DESCRIPTION OF DRAWINGS

The accompanying drawings, which are incorporated in and constitute a part of the specification, illustrate embodiments of the invention and, together with the description, serve to explain the principles of the invention.

FIG. 1 is a schematic sectional view showing an ion beam etching apparatus including a power input device according to the first embodiment of the present invention when viewed from the side;

FIG. 2 is a sectional view taken along a line X-X in FIG. 1;

FIG. 3A is a view for explaining a fluid circulation path for circulating a coolant;

FIG. 3B is a view showing details of a power input mechanism shown in FIG. 2;

FIG. 4 is a sectional view taken along a line Z-Z in FIG. 3A;

FIG. 5A is a sectional view taken along a line Y-Y in FIG. 3A;

FIG. 5B is a view for explaining a fluid circulation path for circulating a coolant in a power input device according to the second embodiment of the present invention;

FIG. 5C is a view showing a power input mechanism in the power input device according to the second embodiment of the present invention;

FIG. 6A is a view for explaining a conventional power input device;

FIG. 6B is a view for explaining the conventional power input device; and

FIG. 7 is a view for explaining the conventional power input device.

### DESCRIPTION OF EMBODIMENTS

Embodiments of the present invention will be described with reference to the accompanying drawings. Note that features including members and arrangements to be described hereinafter merely provide examples in which the present invention is actually practiced, and do not limit the present invention, so various changes and modifications can be made without departing from the scope of the present invention, as a matter of course. Note also that the same reference numerals denote constituent components having the same functions throughout the following drawings, and a repetitive description thereof will not be given.

Although an ion beam etching apparatus will be taken as an example of a vacuum processing apparatus in this embodiment, the scope of the present invention is not limited to this example. A power input device according to the present invention is preferably applicable to, for example, other etching apparatuses and vacuum processing apparatuses including a sputter deposition apparatus, PVD apparatus, and CVD apparatus.

### First Embodiment

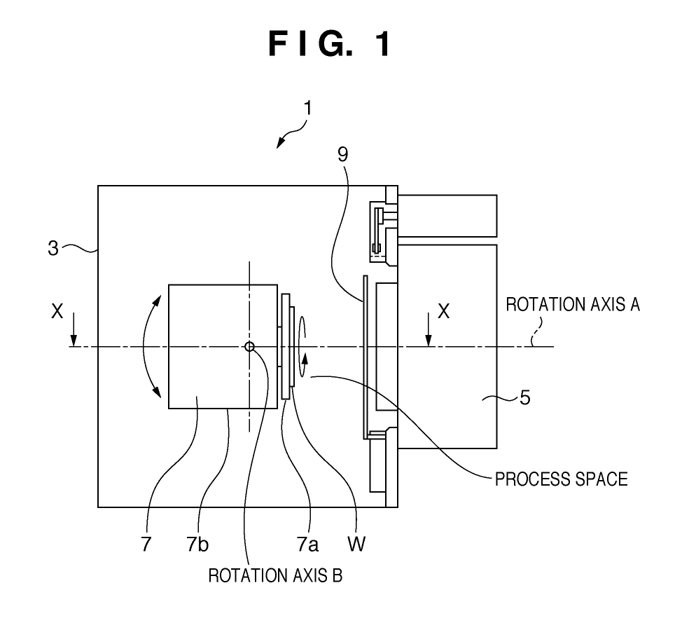

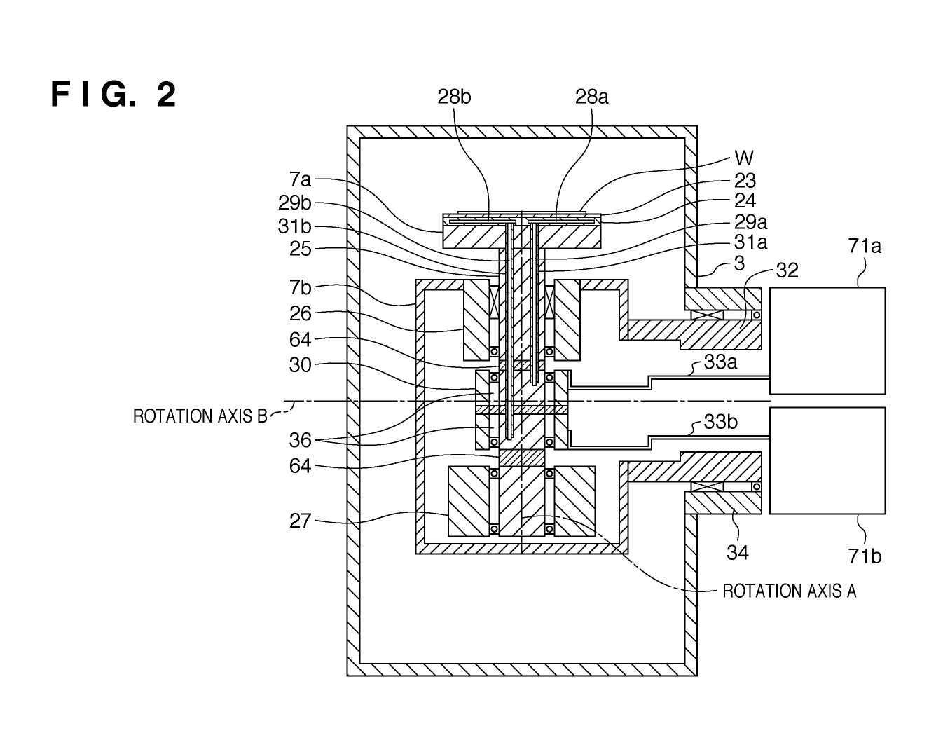

FIG. 1 is a schematic sectional view showing an ion beam etching apparatus including a power input device according to the first embodiment of the present invention when viewed from the side, FIG. 2 is a sectional view taken along a line X-X in FIG. 1, and

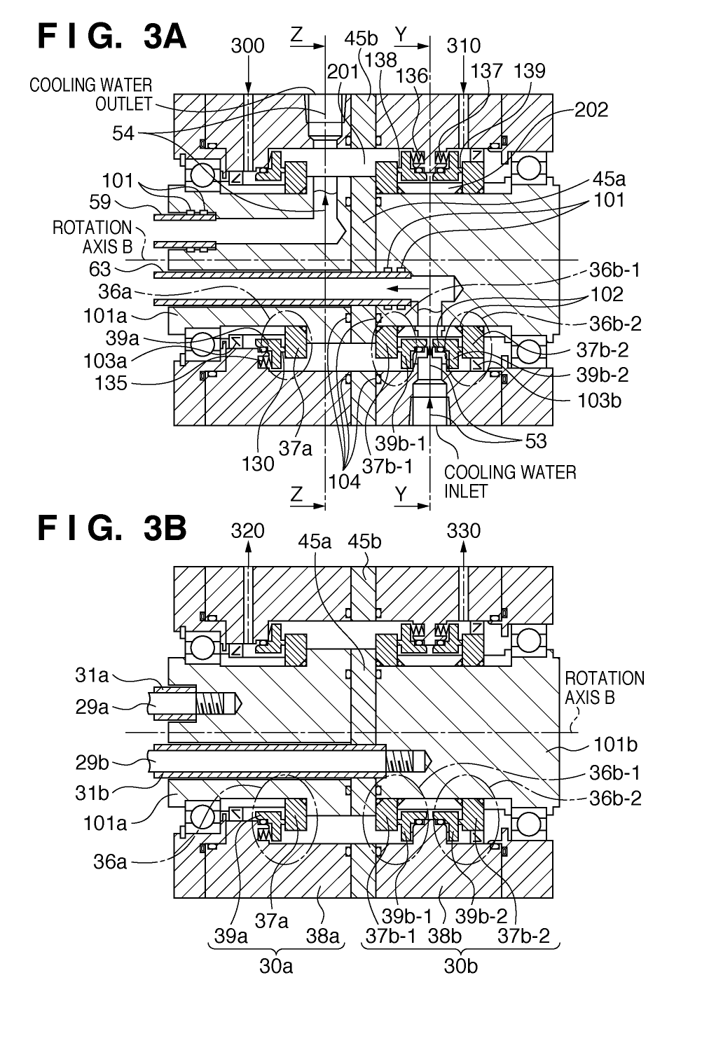

FIGS. 3A and 3B are views showing details of a power input mechanism 30 shown in FIG. 2. Note that to avoid complications, some constituent components of the ion beam etching apparatus are not shown in FIGS. 1, 2, 3A, and 3B. An ion beam etching apparatus 1 bombards a substrate W set on a substrate stage 7 with ions from an ion beam source 5 to form a predetermined stacked film on the substrate W by etching.

The ion beam etching apparatus 1 shown in FIG. 1 includes a vacuum chamber 3 which accommodates the ion beam source 5 serving as an etching source, the substrate stage 7, and a shutter device 9. The ion beam source 5 is disposed on the side surface of the vacuum chamber 3, and the substrate stage 7 is opposed to the ion beam source 5.

The substrate stage 7 includes, as its constituent components, a substrate holder (to be referred to as a “substrate holding portion 7a” hereinafter) which holds the substrate W, and a housing (to be referred to as a “rotation support portion 7b” hereinafter) which supports the substrate holding portion 7a with respect to the vacuum chamber 3. The substrate holding portion 7a can chuck and hold the substrate W by electrostatic attraction using an electrostatic chuck mechanism, and rotate the substrate W together with the substrate holding portion 7a. The rotation support portion 7b is capable of pivoting about a rotation axis B (first rotation axis), and can change the orientation of the substrate holding portion 7a opposed to the ion bombardment surface of the ion beam source 5. That is, the rotation support portion 7b can change the angle of the substrate etching surface with respect to the incident direction of ions emitted by the ion beam source 5. Changing the incident angle of ions on the substrate etching surface makes it possible to obliquely bombard the etching surface of the substrate W with ions to allow high-precision etching.

The ion beam source 5 serves as an apparatus which ionizes a gas using a plasma and bombards the substrate W with the ionized gas. Although Ar gas is ionized in this embodiment, the ions to be emitted are not limited to Ar ions. Kr gas, Xe gas, or O₂ gas, for example, may be ionized. A neutralizer (not shown) for neutralizing the charges of ions emitted by the ion beam source 5 is disposed on the side wall surface of the ion beam source 5.

The shutter device 9 is disposed between the ion beam source 5 and the substrate W on the substrate stage 7, and can block ions, which are emitted toward the substrate W by the ion beam source 5, before they reach the substrate W.

The interior of the substrate stage 7 will be described below with reference to FIG. 2. The rotation support portion 7b serves as a stage capable of rotation about the rotation axis B (first rotation axis). The substrate holding portion 7a serves as a substrate support table including an electrostatic chuck mechanism capable of rotation about a rotation axis A (second rotation axis) extending perpendicularly to the rotation axis B (first rotation axis). The substrate W can be set on the substrate holding portion 7a by the chucking operation of the electrostatic chuck mechanism. The rotation support portion 7b is disposed in the vacuum chamber 3, and the substrate holding portion 7a is disposed above the rotation support portion 7b. A rotary support column 25 (support column) is connected to the bottom surface of the substrate holding portion 7a. The rotary support column 25 made of a conductive material is rotatably fitted in a hole portion, which is formed in the upper portion of the rotation support portion 7b, via a vacuum seal mechanism 26 such as a magnetic fluid seal. With this operation, the interior of the vacuum chamber 3 is maintained airtight. The substrate holding portion 7a fixed to the rotary support column 25 rotates together with the substrate W, which is set on the substrate holding portion 7a, by a rotation mechanism (a rotary drive mechanism 27; to be described later). The power input mechanism 30 includes a first rotary drive mechanism which rotates the rotation support portion 7b about a first rotation axis, and a second rotary drive mechanism which rotates the substrate holding portion 7a about a second rotation axis extending perpendicularly to the first rotation axis.

For example, the rotary drive mechanism 27 is provided below the vacuum seal mechanism 26. The rotary drive mechanism 27 functions as a motor which rotates the rotary support column 25 by interactions between a magnet (not shown) attached to the rotary support column 25 and an electromagnet (not shown) arranged around its outer peripheral surface. The rotary drive mechanism 27 is equipped with an encoder (not shown) which detects the rotation speed and rotation direction of the rotary support column 25.

The substrate holding portion 7a includes a dielectric plate 23 serving as a mounting surface on which the substrate W is set, and an electrostatic chuck (electrostatic chuck device) 24 for pressing and fixing the substrate W set on the dielectric plate 23 against and to the dielectric plate 23 by an appropriate electrostatic attraction force. A fluid flow channel (not shown) is formed in the substrate holding portion 7a to introduce a thermal conduction backside gas to the back side of the substrate W fixed to the dielectric plate 23 by the electrostatic chuck 24. An introduction port is formed in the vacuum seal mechanism 26 to communicate with the fluid flow channel. This backside gas serves to efficiently transfer heat generated by the substrate holding portion 7a cooled by a coolant to the substrate W, and argon gas (Ar) or nitrogen gas, for example, is used conventionally.

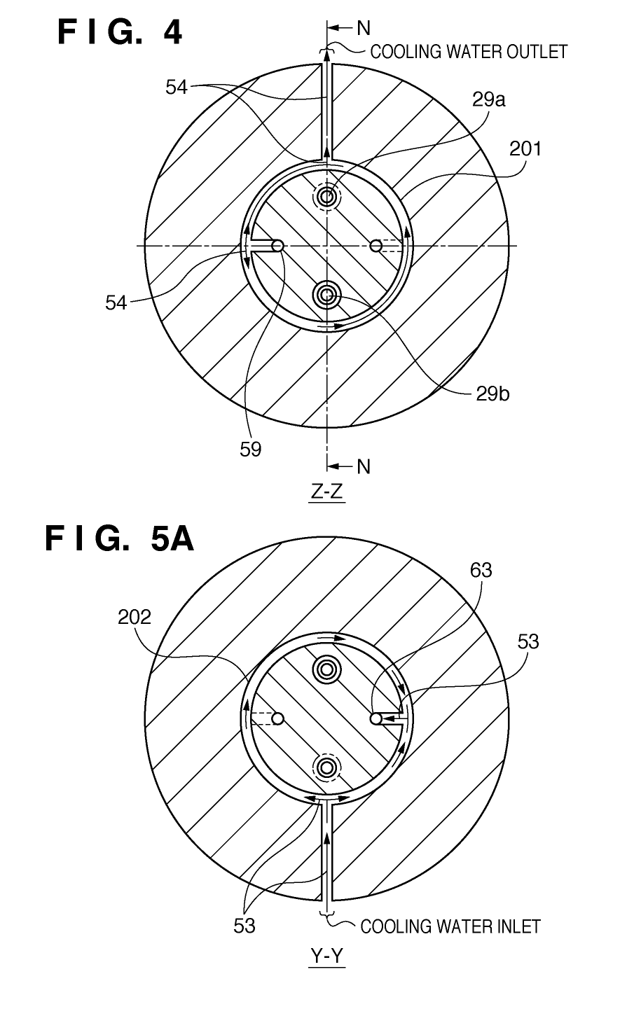

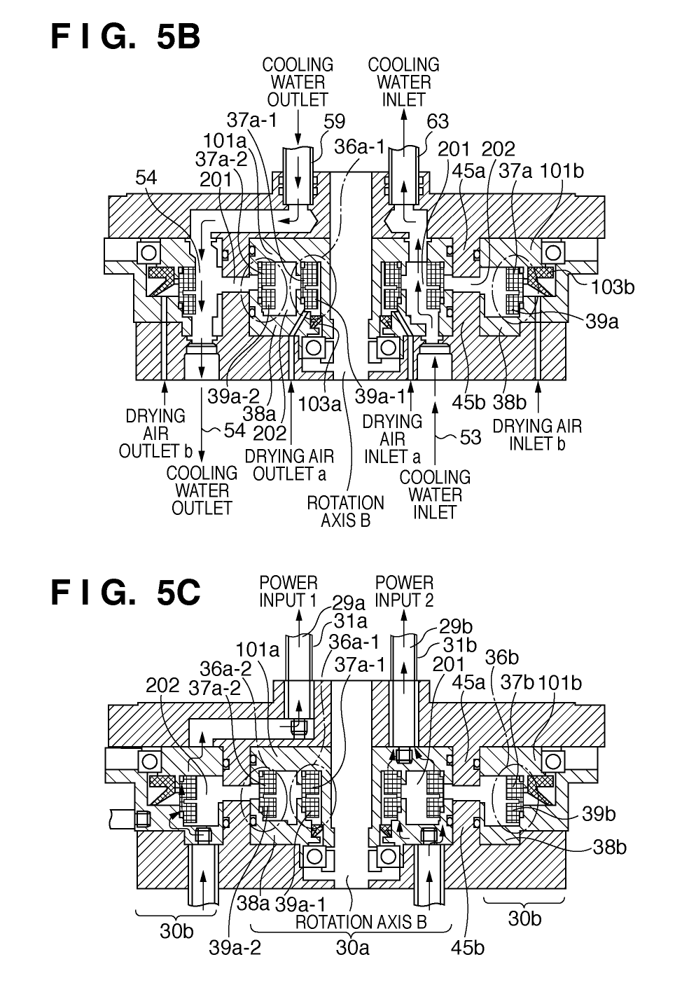

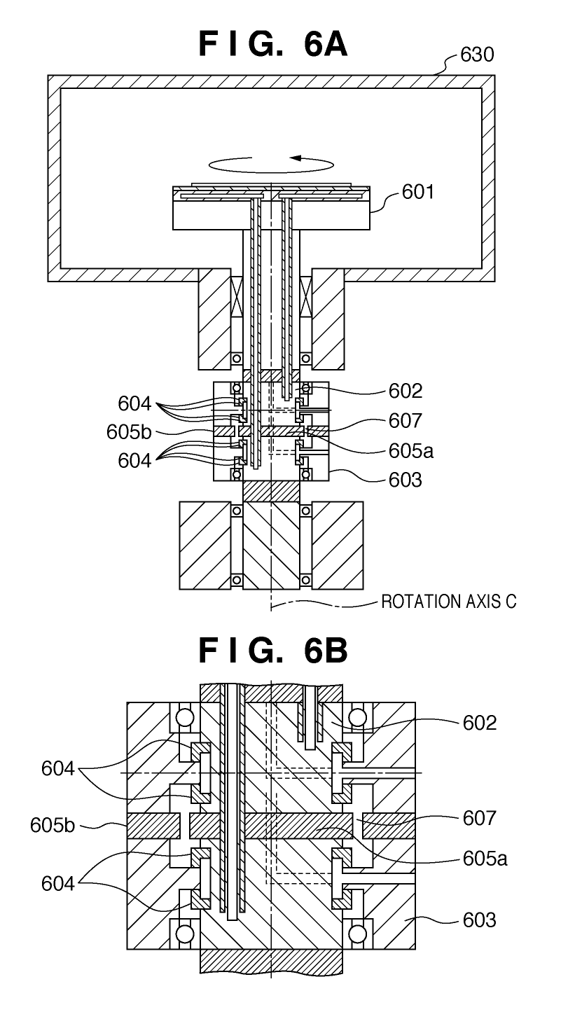

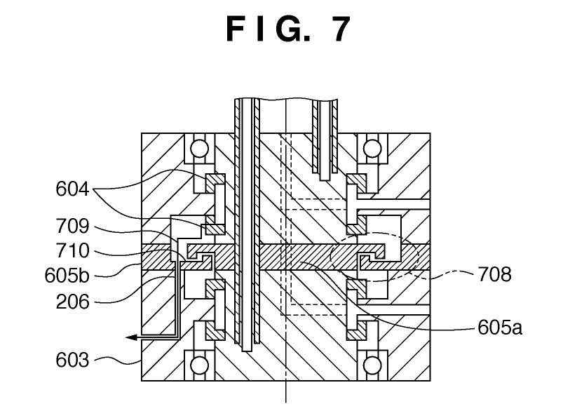

Note that cooling water for cooling the back side of the substrate W is introduced into the substrate holding portion 7a via a cooling water supply pipe 63 (to be described later) shown in FIGS. 4, 5A and 5B, and discharged outside via a cooling water discharge pipe 59.

The electrostatic chuck 24 serves as a positive/negative bipolar chuck device, which includes two electrodes 28a and 28b. The electrode 28a having one polarity, and the electrode 28b having the other polarity are buried in plate-shaped insulating members. A required, first voltage is applied to the electrode 28a via a power input rod 29a (first power input member) extending inside the substrate holding portion 7a and rotary support column 25. A required, second voltage is applied to the electrode 28b via a power input rod 29b (a second power input member) extending inside the substrate holding portion 7a and rotary support column 25. The two power input rods 29a and 29b extend up to the lower portion of the rotary support column 25 and are both covered with insulating members 31a and 31b, respectively, as shown in FIG. 2.

The power input mechanism 30 is disposed in the middle of the rotary support column 25 to supply different voltages for electrostatic chucking (for example, two bias voltages) from external power supplies to the two electrodes 28a and 28b, respectively, of the electrostatic chuck 24. Note that to prevent the power input mechanism 30 from being electrically connected to the vacuum seal mechanism 26 and rotary drive mechanism 27 via the rotary support column 25, insulating members 64 are inserted in the upper and lower portions of the rotary support column 25 to extend through the power input mechanism 30. The power input mechanism 30 is connected to a first voltage supply source 71a, which supplies a first voltage (for example, a DC bias voltage or an RF voltage), via a cable 33a (first voltage supply line) coated with an insulating coating. The power input mechanism 30 is also connected to a second voltage supply source 71b, which supplies a second voltage (for example, a DC bias voltage or an RF voltage), via a cable 33b (second voltage supply line) coated with an insulating coating. Note that the cables 33a and 33b are connected to the power input mechanism 30 and first and second voltage supply sources 71a and 71b, respectively, with sufficient margins so that they do not twist and break even if the unit rotates through a predetermined angle about the rotation axis B. Rotary joints 36 are disposed in the power input mechanism 30. The rotary joints 36 will be described in detail later.

A rotary cylinder 32 is capable of rotation about the rotation axis B, and the rotation support portion 7b is fixed to it. The rotary cylinder 32 is rotatably fitted in a hole portion, which is formed in the vacuum chamber 3, via a vacuum seal mechanism 34 such as a magnetic fluid seal. With this operation, the interior of the vacuum chamber 3 is maintained airtight. The rotary cylinder 32 is rotated by, for example, a servo motor (not shown).

The power input mechanism 30 of the rotary joints 36 will be described in detail with reference to FIG. 3B. A rotary joint 36a includes a conductive annular member 37a (first rotary conductive member) and conductive annular member 39a (first stationary conductive member). The conductive annular member 37a is fixed around a rotary support column 101a which is made of a conductive material and fixed to the rotary support column 25, and is placed at a position on a concentric circle having its center on the rotation axis B. The conductive annular member 39a is fixed to a housing 38a which is made of a conductive material and placed on a circle which is concentric with the rotary support column 101a and has its center on the rotation axis B, and is placed on a concentric circle having its center on the rotation axis B.

Each of the conductive annular members 37a and 39a is arranged on an annular portion 130 in sliding contact with each other in a surface contact state. The conductive annular member 39a is biased against the conductive annular member 37a by an elastic member 135 (for example, a leaf spring, a coil spring, or a rubber member), and functions as an auxiliary mechanism for maintaining airtight the annular portion 130 to be brought into sliding contact. As the rotary support column 25 rotates, the conductive annular members 37a and 39a have a sliding relationship in the rotary joint 36a. The housing 38a is fixed to the rotation support portion 7b, and connected to the first voltage supply source 71a via the conductive cable 33a having a surface coated with an insulating coating material.

Similarly, a rotary joint 36b-1 includes a conductive annular member 37b-1 (second rotary conductive member) and conductive annular member 39b-1 (second stationary conductive member). A rotary joint 36b-2 includes a conductive annular member 37b-2 (second rotary conductive member) and conductive annular member 39b-2 (second stationary conductive member). The two conductive annular members 37b-1 and 37b-2 are fixed around a rotary support column 101b which is made of a conductive material and fixed to the rotary support column 25, and are placed at positions on concentric circles having their centers on the rotation axis B. The conductive annular members 39b-1 and 39b-2 (second stationary conductive members) are fixed to a housing 38b at positions spaced apart from that at which the conductive annular member 39a (first stationary conductive member) is fixed. The two conductive annular members 39b-1 and 39b-2 are fixed to the housing 38b which is made of a conductive material and placed on a circle which is concentric with the rotary support column 101b and has its center on the rotation axis B, and are placed on concentric circles having their centers on the rotation axis B. Each of the conductive annular members 37b-1 and 39b-1 is arranged on an annular portion 138 in sliding contact with each other in a surface contact state. Also, each of the conductive annular members 37b-2 and 39b-2 is arranged on an annular portion 139 in sliding contact with each other in a surface contact state. The conductive annular member 39b-1 is biased against the conductive annular member 37b-1 by an elastic member 136 (for example, a leaf spring, a coil spring, or a rubber member), and functions as an auxiliary mechanism for maintaining airtight the annular portion 138 to be brought into sliding contact. Similarly, the conductive annular member 39b-2 is biased against the conductive annular member 37b-2 by an elastic member 137, and functions as an auxiliary mechanism for maintaining airtight the annular portion 139 to be brought into sliding contact.

As the rotary support column 25 rotates, the conductive annular members 37b-1 and 39b-1 have a sliding relationship in the rotary joint 36b-1. Also, as the rotary support column 25 rotates, the conductive annular members 37b-2 and 39b-2 have a sliding relationship in the rotary joint 36b-2. The housing 38b is fixed to the rotation support portion 7b, and connected to the second voltage supply source 71b via the conductive cable 33b having a surface coated with an insulating coating material.

The power input mechanism 30 can supply DC bias power to the electrostatic chuck 24. The power input mechanism 30 has a structure including two zones electrically isolated by a first insulating member 45a (rotary insulating member) sandwiched between the rotary support columns 101a and 101b, and a second insulating member 45b (stationary insulating member) sandwiched between the housings 38a and 38b. The two isolated zones form a vertical series circuit via the first insulating member 45a and second insulating member 45b.

One of the regions isolated by the first insulating member 45a and second insulating member 45b of the power input mechanism 30 is electrically connected to one of the two electrodes of the electrostatic chuck 24. Also, the other of the regions isolated by the first insulating member 45a and second insulating member 45b of the power input mechanism 30 is electrically connected to the other of the two electrodes of the electrostatic chuck 24. The power input mechanism 30 is divided into an isolated region 30a closer to the electrostatic chuck 24 and an isolated region 30b farther from the electrostatic chuck 24 by the first insulating member 45a and second insulating member 45b. The isolated regions 30a and 30b are insulated from each other. The isolated region 30a and the electrode 28a of the electrostatic chuck 24 are formed inside the rotary support column 25 made of a conductive material, and are electrically connected to each other via the power input rod 29a coated with the insulating member 31a.

Also, the isolated region 30b and the electrode 28b of the electrostatic chuck 24 are formed inside the rotary support column 25, and are electrically connected to each other via the power input rod 29b coated with the insulating member 31b. Note that in the isolated region 30a, the power input rod 29b is covered with the insulating member 31b.

The power input mechanism 30 includes the rotary support columns 101a and 101b and the housings 38a and 38b which respectively surround them. The power input mechanism 30 also includes the first insulating member 45a and second insulating member 45b which divide it into the isolated regions 30a and 30b. The power input mechanism 30 moreover includes the rotary joints 36a, 36b-1, and 36b-2 which are made of a conductive material and serve to slide the rotary support columns 101a and 101b and housings 38a and 38b. The rotary support column 101a, first insulating member 45a, and rotary support column 101b shown in FIG. 3B integrally form the rotary support column 25 (FIG. 2). Also, the housings 38a and 38b and second insulating member 45b shown in FIG. 3B form a housing 38 (FIG. 2).

While the portion from the electrode 28a of the electrostatic chuck 24 to the corresponding isolated region 30a of the power input mechanism 30 is insulated, the power input rod 29a electrically connects the electrode 28a to the corresponding isolated region 30a. Also, while the portion from the electrode 28b of the electrostatic chuck 24 to the corresponding isolated region 30b of the power input mechanism 30 is insulated, the power input rod 29b electrically connects the electrode 28b to the corresponding isolated region 30b.

The isolated region 30a is electrically connected to the conductive housing 38a via the conductive rotary joint 36a. The housing 38a is electrically connected to the first voltage supply source 71a. Also, the isolated region 30b is electrically connected to the conductive housing 38b via the conductive rotary joints 36b-1 and 36b-2. The housing 38b is electrically connected to the second voltage supply source 71b.

According to this embodiment, an electrical path for inputting a predetermined power to the electrostatic chuck 24 can be accommodated in the rotary support column 25. Hence, a path through which power is supplied to the electrostatic chuck 24 can be ensured without routing, for example, electric wires. Also, since the electrical path can be accommodated in the rotary support column 25, the electric circuit can be prevented from short-circuiting upon rotation of the substrate holding portion 7a.

In this embodiment, the power input mechanism 30 is divided into the two insulated, isolated regions 30a and 30b. While the portion from the electrode 28a to the isolated region 30a is insulated, the electrode 28a is electrically connected to the isolated region 30a. Also, while the portion from the electrode 28b to the isolated region 30b is insulated, the electrode 28b is electrically connected to the isolated region 30b. With this configuration, power can be satisfactorily supplied from each power input to the electrostatic chuck 24 while preventing positive and negative voltages supplied to the electrostatic chuck 24 from short-circuiting on the way.

A fluid circulation path for circulating a coolant which cools the substrate holding portion 7a will be described with reference to FIGS. 3A, 4, and 5A. FIG. 3A is a view showing another cross-section of the power input mechanism 30 described with reference to FIG. 3B. FIG. 4 is a sectional view taken along a line Z-Z in FIG. 3A, and FIG. 5A is a sectional view taken along a line Y-Y in FIG. 3A.

A coolant supply mechanism (not shown) circulates pure water (cooling water) having a resistance value controlled to 10 MΩ·cm or more as a coolant. Cooling water flows into the power input device from a cooling water inlet shown in FIG. 5A, and circulates through the flow channel, as indicated by an arrow 53. Pure water (cooling water) is introduced from the cooling water supply pipe 63 into the substrate holding portion 7a via a through hole (not shown) which extends through the rotary support column 25 shown in FIG. 2. Note that the cooling water supply pipe 63 is a pipe-shaped insulating member, which continues from the isolated region 30b to the substrate holding portion 7a. An O-ring 101 made of an elastomer material is configured to appropriately seal the shaft of the pipe-shaped cooling water supply pipe 63.

Pure water (cooling water) supplied to the substrate holding portion 7a via the cooling water inlet, the cooling water supply pipe 63, and the through hole in the rotary support column 25 flows through a cooling water circulation channel (not shown) formed inside the substrate holding portion 7a. The pure water (cooling water) flows into the cooling water discharge pipe 59 shown in FIG. 4 via the through hole (not shown) in the rotary support column 25, and is discharged from a cooling water outlet. The cooling water discharge pipe 59 is a pipe-shaped insulating member, which continues from the substrate holding portion 7a to the isolated region 30a, and the pure water (cooling water) from the substrate holding portion 7a circulates through the flow channel, as indicated by an arrow 54 shown in FIG. 4. The pure water (cooling water) is returned from the cooling water outlet to the coolant supply mechanism (not shown) via a pipe member (not shown), and discharged outside the power input device. The O-ring 101 made of an elastomer material is configured to appropriately seal the shaft of the pipe-shaped cooling water discharge pipe 59. With this configuration, when a coolant (cooling water) circulates through the flow channel, it is prevented from leaking into the isolated regions 30a and 30b. As indicated by the rotary joint 36b-2 shown in FIG. 3A, an O-ring 102 is arranged to seal the gaps between respective members to prevent the cooling water from leaking from the flow channel. An O-ring 104 is arranged also for the same purpose.

The cooling water (coolant) slightly leaked from the sliding contact portion between the conductive annular members 37a and 39a in a sliding relationship is intercepted by disposing a rubber seal member 103a such as an oil seal. A gas supply mechanism (not shown) for vaporizing the leaked cooling water (coolant) supplies a drying gas from a drying air inlet 300 (FIG. 3A), and exhausts and recovers the gas from a drying air outlet 320 (FIG. 3B) toward a gas recovery mechanism (not shown). A gas flow channel (third flow channel) which communicates with the drying air inlet 300 introduces a gas supplied from the gas supply mechanism (not shown) into a space 201 on the side of the outer surfaces of the conductive annular members 37a and 39a. The gas introduced from the gas flow channel (third flow channel) is discharged toward the gas recovery mechanism (not shown) via a gas flow channel (fourth flow channel) which communicates with the drying air outlet 320.

A drying air inlet 310 (FIG. 3A) and drying air outlet 330 (FIG. 3B) are also formed in a space formed by the conductive annular members 37b-2 and 39b-2 and a rubber seal member 103b. A gas flow channel (fifth flow channel) which communicates with the drying air inlet 310 introduces a gas supplied from the gas supply mechanism (not shown) into a space 202 on the side of the outer surfaces of the conductive annular members 37b-2 and 39b-2. The gas introduced from the gas flow channel (fifth flow channel) is discharged toward the gas recovery mechanism (not shown) via a gas flow channel (sixth flow channel) which communicates with the drying air outlet 330.

By introducing a drying gas from the drying air inlets 300 and 310, the leaked coolant (cooling water) intercepted by the sliding contact portion can be vaporized.

Referring to FIG. 3A, the space 201 (coolant discharge space) is formed by the outer peripheral surface of the rotary support column 101a, the inner peripheral surface of the housing 38a opposed to the outer peripheral surface of the rotary support column 101a, the conductive annular members 37a, 37b-1, 39a, and 39b-1, the first insulating member 45a, and the second insulating member 45b. The interior of the space 201 (coolant discharge space) is maintained airtight. The space 201 (coolant discharge space) forms a flow channel for supplying the coolant (cooling water) flowing from the cooling water discharge pipe 59 shown in FIG. 4 to the cooling water outlet.

A space 202 (coolant supply space) is formed by the outer peripheral surface of the rotary support column 101b, the inner peripheral surface of the housing 38b opposed to the outer peripheral surface of the rotary support column 101b, and the conductive annular members 37b-1, 37b-2, 39b-1, and 39b-2. The interior of the space 202 (coolant supply space) is maintained airtight. The space 202 (coolant supply space) forms a flow channel for circulating and supplying the coolant (cooling water) flowing from the cooling water inlet shown in FIG. 5A to the cooling water supply pipe 63.

Circulating a coolant (cooling water) into the spaces 201 and 202 formed by the rotary joints 36, 36b-1, and 36b-2 also produces an effect of removing heat generated by the rotary joints 36, 36b-1, and 36b-2, thereby improving the lubricity of the conductive annular members which slide against each other. This considerably prolongs the lives of the conductive annular members.

The conductive annular member 37b-1 and rotary support column 101a are both conductive members, which prevent the isolated regions 30a and 30b from being electrically connected to each other by setting an appropriate creepage distance for insulation against a supply voltage via the first insulating member 45a. At the same time, the housings 38a and 38b are both conductive members, which prevent the isolated regions 30a and 30b from being electrically connected to each other by setting an appropriate creepage distance for insulation against a supply voltage via the second insulating member 45b. Also, the coolant (cooling water) is pure water having a resistance value controlled to 10 MΩ·cm or more, so the isolated regions 30a and 30b are not electrically connected to each other via the coolant (cooling water), either.

A supply line which supplies the coolant (cooling water) to the substrate holding portion 7a, and a discharge line which discharges the coolant (cooling water) returned from the substrate holding portion 7a are separated by a surface sliding portion in which the conductive annular members 39b-1 and 37b-1 are set in a surface contact state. Even if the coolant leaks from the supply line side to the discharge line side upon passing through the surface sliding portion, the coolant (cooling water) remains in a circulation path having a resistance value controlled to a predetermined value or more by, for example, an ion-exchange resin built into the coolant supply mechanism (not shown). This makes it possible to prevent the cable 33a (first voltage supply line) connected to the first voltage supply source 71a and the cable 33b (second voltage supply line) connected to the second voltage supply source 71b from being electrically connected to each other via the coolant (cooling water).

### Second Embodiment

A power input device including a plurality of conductive annular members 37a, 39a, 37b, and 39b arranged in the rotation axis direction of a substrate has been described above in the first embodiment.

However, a power input device including a plurality of conductive annular members 37a, 39a, 37b, and 39b juxtaposed in the radial direction of a circle having its center on the rotation axis of a substrate, that is, in a concentric circular shape having its center on the rotation axis of the substrate, as shown in FIGS. 5B and 5C, can also be adopted. By juxtaposing the plurality of conductive annular members 37a, 39a, 37b, and 39b in a concentric circular shape having its center on the rotation axis of the substrate, the length of the overall power input device can be made smaller than the conventional power input device to a plurality of electrodes having different polarities, thereby achieving a compact unit. Although conductive annular members in the second embodiment corresponding to the conductive annular members 37a, 39a, 37b, and 39b in the first embodiment are different from each other in size and shape, the former are imparted with the same functions as the latter and therefore denoted by the same reference numerals.

FIG. 5B is a view for explaining a fluid circulation path for circulating a coolant in a power input device according to the second embodiment of the present invention. FIG. 5C is a view showing a power input mechanism in the power input device according to the second embodiment of the present invention. The power input device according to this embodiment is configured by juxtaposing a plurality of conductive annular members in a concentric circular shape having its center on the rotation axis of a substrate. For this reason, a housing is opposed to the end portion (the end portion opposite to the substrate holder side) of a rotary support column (support column). Also, the housing according to this embodiment is formed so that a water channel and a power input rod extend through the wall surface of the housing opposed to the end portion of the rotary support column so as to pass the coolant and power input pipe inside and outside the power input device in the rotation axis direction of the support column. The same reference numerals denote members which constitute the power input device according to the second embodiment and have the same functions as in the first embodiment, and a detailed description thereof will not be given.

According to this embodiment, it is possible to provide a power input technique which allows stable power input to a substrate holder having a plurality of electrodes, and is applicable to an apparatus which processes a substrate upon pivoting a substrate holder while a normal to the substrate holding surface of the substrate holder is set perpendicular to the direction of gravity.

Although the space 202 is formed between a set of conductive annular members (second stationary conductive members) 39b-1 and 39b-2 and a set of conductive annular members (second rotary conductive members) 37b-1 and 37b-2 in the above-mentioned embodiments, the set of conductive annular members 39b-2 and 37b-2 may not be used. In this case, other rotary seal members must be used in place of the conductive annular members 39b-2 and 37b-2.

The present invention is not limited to the above-described embodiments, and various changes and modifications can be made within the spirit and scope of the present invention. Therefore, to apprise the public of the scope of the present invention, the following claims are made.

1. A power input device comprising:
a substrate holder which is accommodated in a vacuum chamber and capable of holding a substrate;
a support column connected to said substrate holder;
a housing which rotatably supports said support column;
a rotary drive unit which rotates said substrate holder via said support column;
a power input unit which inputs externally supplied power to said substrate holder via said support column; and
a coolant supply mechanism which circulates an externally supplied coolant to said substrate holder,
said power input unit including
a first stationary conductive member disposed in said housing,
a second stationary conductive member which is disposed in said housing at a position spaced apart from said first stationary conductive member, and is insulated from said first stationary conductive member,
a first rotary conductive member disposed on said support column in sliding contact with said first stationary conductive member,
a second rotary conductive member which is disposed on said support column in sliding contact with said second stationary conductive member, and insulated from said first rotary conductive member,
a first power input member which supplies a first voltage to said substrate holder via said first rotary conductive member and said first stationary conductive member, and
a second power input member which supplies a second voltage to said substrate holder via said second rotary conductive member and said second stationary conductive member,
wherein the coolant circulates through a space formed by a surface of said support column, said housing opposed to the surface of said support column, said first rotary conductive member, said first stationary conductive member, said second rotary conductive member, and said second stationary conductive member, and
the space is connected to said coolant supply mechanism via a coolant flow channel formed in said support column.

2-10. (canceled)

11. A power input device comprising:
a substrate holder capable of holding a substrate;
a support column connected to said substrate holder;
a housing which rotatably supports said support column;
a first rotary conductive member disposed on said support column;
a second rotary conductive member which is disposed on said support column and insulated from said first rotaly conductive member;
a first stationary conductive member disposed in said housing in sliding contact with said first rotary conductive member;
a second stationary conductive member disposed in said housing in sliding contact with said second rotary conductive member;
a first power input member which supplies a first voltage to said substrate holder via said first rotary conductive member and said first stationary conductive member; and
a second power input member which supplies a second voltage to said substrate holder via said second rotary conductive member and said second stationary conductive member,
wherein a coolant is capable of circulating through a space formed by a surface of said support column, said housing, said first rotary conductive member, said first stationary conductive member, said second rotary conductive member, and said second stationary conductive member, and
wherein the coolant is supplied to said substrate holder via the space.

12. The power input device according to claim 11, wherein
both said first rotary conductive member and said second rotary conductive member are disposed on an outer peripheral surface of said support column,
said second stationary conductive member is disposed in said housing at a position spaced apart from said first stationary conductive member in a rotation axis direction, and
the space is formed by the outer peripheral surface of said support column, an inner peripheral surface of said housing, that is opposed to the outer peripheral surface of said support column, said first rotary conductive member, said first stationary conductive member, said second rotary conductive member, and said second stationary conductive member.

13. The power input device according to claim 11, wherein
both said first rotary conductive member and said second rotary conductive member are disposed at an end portion of said support column,
said second stationary conductive ember is fixed to said housing at a position spaced apart from said first stationary conductive member in a radial direction of said support column, and
the space is formed by a surface of the end portion of said support column, a surface of said housing, that is opposed to the surface of the end portion of said support column, said first rotary conductive member, said first stationary conductive member, said second rotary conductive member, and said second stationary conductive member.

14. The power input device according to claim 11, wherein
said coolant flow channel includes
a first flow channel configured to supply the coolant from said coolant supply mechanism to said substrate holder via said housing and said support column, and
a second flow channel configured to discharge the coolant from said substrate holder via said support column and said housing.

15. The power input device according to claim 14, wherein
said second rotary conductive member is formed by two ring-shaped members that are disposed on said support column and spaced apart from each other in the rotation axis direction of said support column,
said second stationary conductive member is formed by two ring-shaped members disposed in said housing in sliding contact with the two ring-shaped members, respectively, of said second rotary conductive member,
a second space is formed by the surface of said support column, the surface of said housing, that is opposed to the outer peripheral surface of said support column, the two ring-shaped members of said second rotary conductive member, and the two ring-shaped members of said second stationary conductive member, and
the second space has an airtightly maintained interior and communicates with said first flow channel.

16. The power input device according to claim 14, wherein
said second flow channel communicates with the space,
the space has an airtightly maintained interior,
a rotary insulating member which insulates said first rotary conductive member and said second rotary conductive member from each other is disposed on said support column that forms the space, and
a stationary insulating member which insulates said second stationary conductive member and said first stationary conductive member from each other is disposed on the surface of said housing that forms the space.

17. The power input device according to claim 16, further comprising:
a third flow channel configured to introduce a gas supplied from a gas supply mechanism into the space on a side of outer surfaces of said first rotary conductive member and said first stationary conductive member; and
a fourth flow channel configured to discharge the gas introduced from said third flow channel to a gas recovery mechanism.

18. The power input device according to claim 17, further comprising:
a fifth flow channel configured to introduce a gas supplied from a gas supply mechanism into a coolant supply space on a side of outer surfaces of said second rotary conductive member and said second stationary conductive member; and
a sixth flow channel configured to discharge the gas introduced from said fifth flow channel to a gas recovery mechanism.

19. The power input device according to claim 11, further comprising:
a first rotary drive mechanism which rotates said housing about a first rotation axis; and
a second rotary drive mechanism which rotates said substrate holder about a second rotation axis extending perpendicularly to the first rotation axis.

20. A vacuum processing apparatus including a substrate holder which is accommodated in a vacuum processing chamber, and includes an electrostatic chuck device configured to hold a substrate to undergo predetermined vacuum processing, wherein power is input to the electrostatic chuck device via a power input device defined in claim 11.
